(19) United States
(12) Patent Application Publication
(10) Pub. No.: US 2006/0037640 A1
(43) Pub. Date: Feb. 23, 2006

(54) Solar cell device, method for manufacture thereof, and electronic device

(75) Inventor: Hirotsuna Miura, Fujimi-machi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/968,042

(22) Filed: Oct. 20, 2004

(30) Foreign Application Priority Data
Nov. 5, 2003 (JP) 2003-375701

(51) Int. Cl. H02N 6/00; H01L 25/00

(52) U.S. Cl. 136/246

(57) ABSTRACT

Exemplary embodiments provide a solar cell device with a high power generation efficiency. A plurality of generating elements that generate electricity under the effect of incident light are formed on a substrate. Lens portions are provided on the incidence side of the light for each generating element to converge the light and guide it to the generating elements.

### BACKGROUND OF THE INVENTION

1. Field of Invention

The present invention relates to a solar cell device, a method for the manufacture thereof, and an electronic device.

2. Description of Related Art

In the field of solar cells, the related art includes solar cells in which a plurality of solar cell elements are stacked (referred to as tandem solar cells) to increase energy conversion efficiency.

In such solar cells, light in a wide wavelength band is effectively absorbed by disposing a solar cell element film (for example, a monocrystalline film) to receive light with a comparatively short wavelength in the vicinity of light-receiving surface, and disposing a solar cell element film (for example, monocrystalline silicon germanium) to absorb light with a comparatively long wavelength in a position far from the light-receiving surface.

Further, the related art includes solar cells in which a plurality of solar cell elements are arranged two-dimensionally in order to increase the light-receiving surface area of the solar cells (referred to as two-dimensional arrangement integrated solar cells).

A method of forming a plurality of solar cell element films in a row on a large substrate by using a plasma CVD method or the like is used in the related art as a method for the manufacture of such solar cells.

However, a large substrate is difficult to form from monocrystalline silicon or polysilicon.

A technology of producing a solar cell by pasting a pair of electrode units including solar cell element films is disclosed in JP-A-2001-53299.

Further, a technology for the manufacture of a solar cell by using a printing method is disclosed in JP-A-10-150213.

### SUMMARY OF THE INVENTION

However, the following problems are associated with the above-described related art technology.

The problem associated with the technology of JP-A-2001-53299 is that cost increases if pasting is conducted over the entire surface of large substrates.

Furthermore, because each of the solar cell elements disposed two-dimensionally is very small, light utilization efficiency can hardly be considered sufficient and the development of solar cells that excel in generation efficiency is desired. Further, the technology disclosed in JP-A-10-150213 uses a lenticular lens or fly-eye lens to enable the reception of light radiation averaged with respect to illumination angle changes during the time of day or year. However, with those lenses, because the incident light was diffused, it made a contribution to averaging the luminosity distribution, but it could not be considered sufficient for increasing the generation efficiency, for example, increasing the aperture ratio of each solar cell element.

With the foregoing and/or other issues in view, the present invention provides a solar cell device with a high generation efficiency, a method for the manufacture thereof, and an electronic device.

The present invention provides a low-cost solar cell device, a method for manufacture thereof, and an electronic device.

In order to address or attain the above, an exemplary aspect of the present invention can employ the following exemplary constitution.

A solar cell device in accordance with an exemplary aspect of the present invention includes a plurality of generating elements, that generate electricity under the effect of incident light, and that are formed on a substrate. Lens portions are provided on the incidence side of the light for each generating element, converging the light and guiding it to the generating elements.

Therefore, in accordance with an exemplary aspect of the present invention, the light falling on the lens portion can be converged and guided to the generating elements. As a result, the aperture ratio increases and the generation efficiency can be increased.

It may be preferred that the generating elements be formed on a second substrate different from the aforementioned substrate, and are peeled off from the second substrate and transferred onto the aforementioned substrate.

As a result, in accordance with an exemplary aspect of the present invention, a multiplicity of generating elements disposed in a dispersed fashion with a spacing therebetween on a substrate can be integrally manufactured on the second substrate. Therefore, the surface area efficiency in the element manufactured can be increased by comparison with the case where the generating elements are directly formed on the substrate, and a substrate with generating elements disposed in a dispersed fashion can be manufactured at low cost and with good efficiency.

Further, because the second substrate is not required to be large, unimpeded manufacture is possible even when a plurality of generating elements are disposed on a large substrate.

Further, a constitution is also advantageous in which some generating elements of a plurality of generating elements formed on the second substrate are selectively transferred onto the aforementioned substrate.

As a result, the generating elements can be easily disposed in any number in any location on the substrate. Moreover, the generating elements manufactured on the second substrate can be sorted and discarded prior to the transfer and the production yield can be increased.

A constitution in which the lens portions are formed by a liquid drop ejection system is also advantageous. In this case, minute lens portions can be formed at predetermined positions with a high degree of accuracy and at low cost.

In this case, a constitution is preferred in which the lens portions are provided on a third substrate that is supported so that the distance therefrom to the aforementioned substrate can be adjusted.

As a result, the distance between the lens portions and generating elements can be freely adjusted and the light illumination range of generating elements can be easily adjusted, for example, the focal position of the lens portions can be adjusted.

Further, a constitution can be also employed in which the lens portions are provided so that they cover the generating elements.

In this case, a spherical surface can be easily formed by surface tension of liquid drops. Moreover, because self-arrangement ability is used, the alignment of optical axes is unnecessary.

When the lens portions are provided on the substrate, the advantageous constitution includes a protrusion having lyophilic property and provided, with a difference in level with the substrate, around the generating elements.

As a result, liquid drops can be supplied in a state in which they are not repelled from the protrusion. Therefore, a lens portion with a shape that is closer to the spherical surface can be formed on the protrusion. Furthermore, a focal distance can be also adjusted by adjusting the droplet amount.

In an exemplary or preferred disposition of generating elements, they are disposed in a zigzag formation on the substrate.

As a result, minute lens portions of an almost round shape in a plan view thereof are provided, and light can be received with good efficiency.

On the other hand, the electronic device in accordance with an exemplary aspect of the present invention includes the above-described solar cell device as a power source unit.

Therefore, in accordance with an exemplary aspect of the present invention, an inexpensive electronic device with excellent power generation efficiency can be obtained because it has inexpensive power source with a high power generation efficiency.

Further, a method for the manufacture of a solar cell device in accordance with an exemplary aspect of the present invention is a method for the manufacture of a solar cell device that includes a plurality of generating elements, that generate electricity under the effect of incident light, and that are formed on a substrate. The method includes providing lens portions converging the light, and guiding it to the generating elements on the incidence side of the light for each generating element.

Therefore, in accordance with an exemplary aspect of the present invention, the light falling on the lens portion can be converged and guided to the generating elements. As a result, the aperture ratio increases and generation efficiency can be raised.

### BRIEF DESCRIPTION OF THE DRAWINGS

FIG. 1 is a partial plan view of the solar cell device in accordance with an exemplary embodiment of the present invention;

FIG. 2 is an enlarged cross-sectional view of a significant portion of the solar cell device;

FIGS. 3(a) and 3(b) are partial cross-sectional views of a transfer substrate;

FIG. 4 is a schematic perspective view of the droplet ejection device;

FIG. 5 is a schematic that illustrates the liquid ejection principle based on using a piezoelectric system;

FIGS. 6(a)-6(c) are schematics that illustrate the sequence operations in the manufacture of the solar cell device;

FIG. 7 is an enlarged cross-sectional view of a significant portion of the solar cell device of the second exemplary embodiment;

FIG. 8 is an enlarged cross-sectional view of a significant portion of the solar cell device of the third exemplary embodiment; and

FIG. 9 is a schematic that illustrates a specific example of the electronic device employing the solar cell device in accordance with an exemplary embodiment of the present invention.

### DETAILED DESCRIPTION OF PREFERRED EMBODIMENTS

Exemplary embodiments of the solar cell device in accordance with the present invention, a method for the manufacture thereof, and an electronic device, are explained below with reference to FIGS. 1 to 9.

### First Exemplary Embodiment

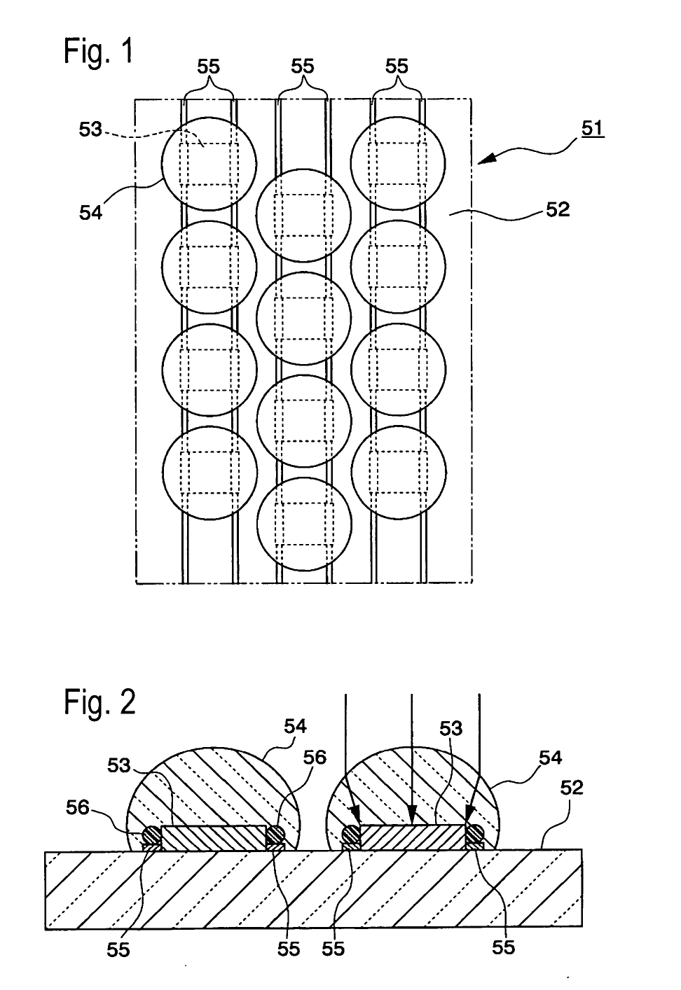

FIG. 1 is a partial plan view of the solar cell device. FIG. 2 is a cross-sectional view in which significant portions are enlarged.

As shown in FIG. 1, in a solar cell device 51, a plurality of generating elements 53 formed from polysilicon (or single-crystal silicon) and lens portions 54 formed from a radiation-curable resin are arranged in pairs on a substrate 52 from glass or the like. Furthermore, wirings 55 extending in the Y axis direction for leading out the electric current from the generating elements 53 are formed with a spacing in the X axis direction.

Further, the generating elements 53 and lens portions 54 are arranged in a zigzag formation such that they have an almost constant pitch in the Y axis direction on the wirings 55, and the columns adjacent in the X axis direction are shifted by half a pitch with respect to each other.

As shown in FIG. 2, the generating elements 53 are fixed between the wirings 55, 55 on the substrate 52 via an electrically conductive adhesive 56, and the lens portions 54 are provided in an almost semispherical shape on the incidence side (upper side in FIG. 2) of the light falling on the generating elements 53.

Actually, a protective glass or the like is provided above those generating elements 53 and lens portions 54, but it is not shown in the figure for the sake of convenience.

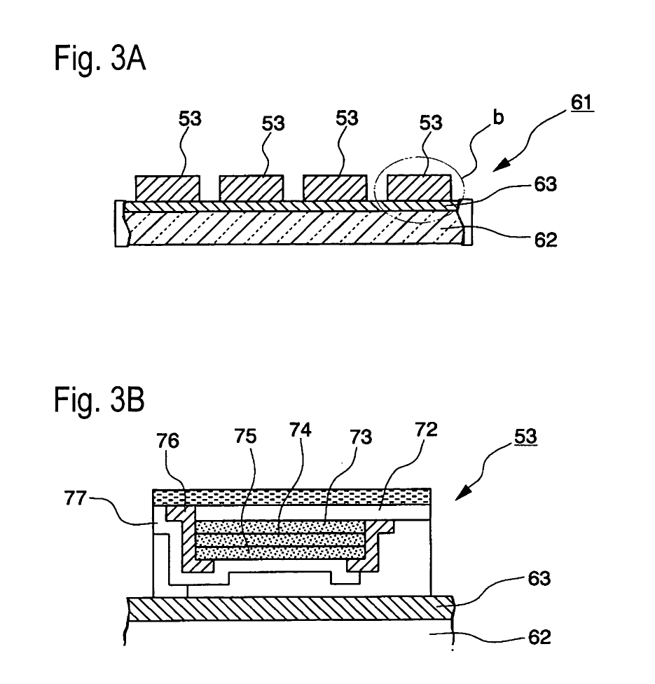

Further, as shown in FIG. 3(a) a plurality of generating elements 53 are formed in advance on a transfer substrate 61. The transfer substrate 61 has a configuration in which a peeling layer 63 is formed on a transparent heat-resistant substrate (second substrate) 62, for example, from quartz glass capable of withstanding about 1000° C., and a plurality of generating elements 53 are formed on the peeling layer 63. No specific limitation is placed on the thickness of the transparent heat-resistant substrate 62, but if the substrate thickness is too small, the strength thereof is decreased. On the other hand, if the thickness is too large, it causes the below-described attenuation of illuminating light when the transmittance of the substrate is low. Therefore, the thickness is preferably about 0.1 mm to 5.0 mm, more preferably about 0.5 mm to 1.5 mm.

The pealing layer 63 demonstrates peeling inside the layer or at the interface (“intralayer peeling” or “interface peeling”) under illuminating light, such as laser light. Thus, when illumination is conducted with an illuminating light of fixed intensity, then a bonding strength between atoms or molecules in atoms or molecules constituting the constituent substance is lost or decreased, thereby causing ablation or the like and inducing peeling. Furthermore, under irradiation with illuminating light, the components contained in the peeling layer 63 become gases and are emanated, leading to separation, or the peeling layer 63 absorbs light and becomes a gas and the vapor thereof is emitted, leading to separation.

For example, amorphous silicon (a-Si) can be used as the composition of the peeling layer 63. This amorphous silicon may contain hydrogen (H). It is preferred that the content of hydrogen be about 2 at. % or more, more preferably 2-20 at. %. If hydrogen is contained, the hydrogen is emanated under light illumination, the internal pressure is generated in the peeling layer 63 and peeling thereof is enhanced. The content of hydrogen is adjusted by appropriately setting the film formation conditions, for example, when a CVD method is used, such conditions as the composition of gas, gas pressure, gas atmosphere, gas flow rate, gas temperature, substrate temperature, and supplied power. Examples of other peeling layer materials include silicon oxide or silicic acid compounds, nitride ceramics such as silicon nitride, aluminum nitride, and titanium nitride, organic polymer materials (materials in which atomic bonds are broken by light illumination), metals, for example, Al, Li, Ti, Mn, In, Sn, Y, La, Ce, Nd, Pr, Gd, or Sm, or alloys containing at least one thereof.

As for the thickness of the peeling layer 63, if the thickness of the peeling layer 63 is too small, then thickness uniformity of the film formed is lost and peeling becomes nonuniform. If the thickness of the peeling layer 63 is too large, then power (quantity of light) of the illuminating light which is required for peeling has to be increased. Furthermore, a long time is required to remove the residue of the peeling layer 63 remaining after peeling. Therefore, the thickness of the peeling layer is preferably about 1 nm to 20 μm, more preferably about 10 nm to 2 μm, and even more preferably about 20 nm to about 1 μm.

Any method capable of forming the peeling layer 63 of uniform thickness may be used as a method of forming the peeling layer 63, and an appropriate method can be selected according to conditions, such as the composition or thickness of the peeling layer 63. Examples of suitable methods include various vapor deposition methods, such as CVD (including MOCCVD, low-pressure CVD, ECR-CVD) method, deposition, molecular beam deposition, sputtering, ion plating, and PVD, various plating methods such as electroplating, dip plating (dipping), and electroless plating, coating methods such as Langmuir-Blodgett (LB) method, spin coating method, spray coating method, and roll coating method, and various printing methods, transfer method, ink jet method, and powder jet method. Two or more such methods may be used in combination.

In particular, when the composition of the peeling layer 63 is amorphous silicon (a-Si), it is preferred that the film be formed by a CVD method, in particular, low-pressure CVD or plasma CVD. Further, when the ceramic peeling layer 63 is formed by a sol-gel process or when it is composed of an organic polymer material, it is preferred that a coating method, in particular, spin coating method be used.

FIG. 3(b) is a cross-sectional view illustrating an example of a pin-type generating element 53 used in the present exemplary embodiment. The generating element 53 is composed by successively laminating an electrically conductive film 72, a n-type semiconductor layer 73, an i-type semiconductor layer 74, a p-type semiconductor layer 75, an insulating layer 76, and a transparent electrically conductive film.

A method for the manufacture of the generating element 53 is well known and explanation thereof is, therefore, omitted.

A droplet ejection apparatus used in the formation of lens portions 54 of the solar cell device 51 of the above-described configuration is explained below.

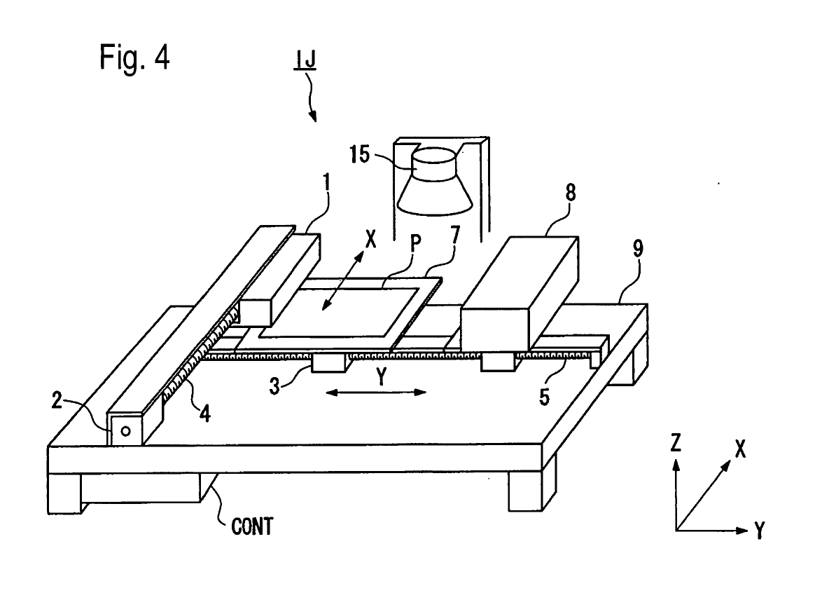

FIG. 4 is a schematic perspective view illustrating the configuration of a droplet ejection apparatus IJ.

The droplet ejection apparatus IJ includes a droplet ejection head 1, an X axis direction dive shaft 4, an Y axis direction drive guide shaft 5, a control unit CONT, a stage 7, a cleaning mechanism 8, a base 9, and a heater 15.

The stage 7 supports a substrate P (the aforementioned substrate 52) to provide an ink (functional liquid) with the droplet ejection apparatus IJ and includes a fixing mechanism (not shown in the figure) to fix the substrate P in a standard position.

The droplet ejection head 1 is a droplet ejection head of a multinozzle type including a plurality of ejection nozzles, and the longitudinal direction thereof is matched with the Y axis direction. A plurality of ejection nozzles are provided with a constant spacing in a row in the Y axis direction on the lower surface of the droplet ejection head 1. An ink including the above-described lens-forming material is ejected from the ejection nozzles of the droplet ejection head 1 onto the substrate P supported on a stage 7.

An X axis direction drive motor 2 is connected to an X axis direction drive shaft 4. The X axis direction drive motor 2 is a stepping motor or the like and rotates the X axis direction drive shaft 4 if a drive signal for the X axis direction is supplied from the control unit CONT. If the X axis direction drive shaft 4 rotates, the droplet ejection head 1 moves in the X axis direction.

An Y axis direction guide shaft 5 is fixed so as to be immovable with respect to the base 9. The stage 7 includes an Y axis direction drive motor 3. The Y axis direction drive motor 3 is a stepping motor or the like, and moves the stage 7 in the Y axis direction if a drive signal for the Y axis direction is supplied from the control unit CONT.

The control unit CONT supplies a voltage to control the ejection of droplets to the droplet ejection head 1. Further, it supplies a drive pulse signal to control the movement of the droplet ejection head 1 in the X axis direction to the X axis direction drive motor 2, and a drive pulse signal to control the movement of the stage 7 in the Y axis direction to the Y axis direction drive motor 3.

The cleaning mechanism 8 serves to clean the droplet ejection head 1. The cleaning mechanism 8 is provided with a motor to drive in the Y axis direction (not shown in the figure). Under driving from the motor that drives in the Y axis direction, the cleaning mechanism moves along the Y axis direction guide shaft 5. The movement of the cleaning mechanism 8 is also controlled by the control unit CONT.

The heater 15 heat treats the substrate P by lamp annealing, and serves to conduct evaporation and drying of the solvent contained in the liquid material coated on the substrate P. Connection of the heater 15 to, and disconnection from, the power source is also controlled by the control unit CONT.

The droplet ejection apparatus IJ ejects droplets onto the substrate, while the droplet ejection head 1 and the stage 7 supporting the substrate P are scanned with respect to each other. In the explanation given below, the X axis direction is considered to be a scanning direction and the Y axis direction, which is perpendicular to the X axis direction, is considered to be a non-scanning direction. Therefore, the ejection nozzles of the droplet ejection head 1 are provided in a row with equal spacing in the Y axis direction, which is a non-scanning direction. Further, referring to FIG. 1, the droplet ejection head 1 is disposed at a right angle with respect to the advance direction of the substrate P, but the angle of the droplet ejection head 1 may be adjusted to provide for intersection with the advance direction of the substrate P.

As a result, adjusting the angle of the droplet ejection head 1 makes it possible to adjust the pitch between the nozzles. Furthermore, a configuration may also be used in which the distance between the substrate P and nozzle surface can be randomly adjusted.

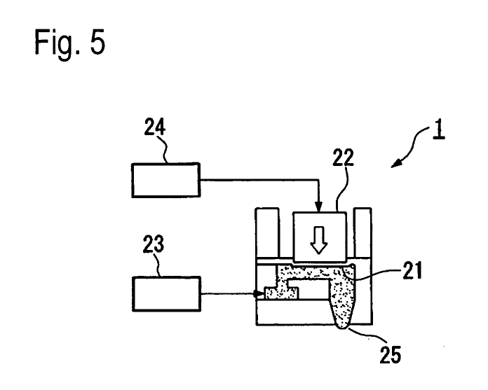

FIG. 5 illustrates the ejection principle of a liquid material with a piezoelectric system.

Referring to FIG. 5, a piezoelectric element 22 is disposed adjacently to a liquid chamber 21 accommodating a liquid material (lens molding material, functional liquid). The liquid material is supplied to the liquid chamber 21 via a liquid material supply system 23 including a material tank to accommodate the liquid material. The piezoelectric element 22 is connected to the drive circuit 24, a voltage is applied to the piezoelectric element 22 via the drive circuit 24, and due to the deformation of the piezoelectric element 22, the liquid chamber 21 is deformed and the liquid material is discharged from the nozzle 25. In this case, the degree of deformation of the piezoelectric element 22 can be controlled by changing the value of the applied voltage. Furthermore, the deformation rate of the piezoelectric element 22 can be controlled by changing the frequency of the applied voltage. The advantage of droplet ejection using the piezoelectric system is that no heat is provided to the material, and no effect is produced on the composition of the material.

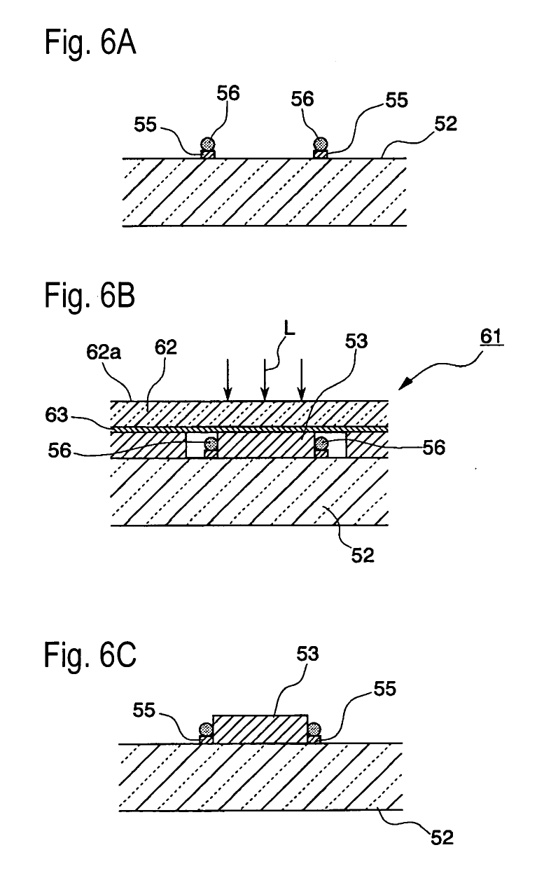

The sequence of operations employed in manufacturing the solar cell device 51 is explained hereinbelow with reference to FIGS. 6(a)-6(c). To facilitate understanding, in those figures, all the layers and components are shown in a simplified form and the scale thereof is changed.

First, as shown in FIG. 6(a), a wiring 55 is formed on the substrate 52 by using related art or the conventional technology, such as sputtering or photolithography, and an electrically conductive adhesive 56 is coated on the wiring 55. The wiring may also be formed by ejecting a liquid body containing fine metal particles with the droplet ejection device IJ (droplet ejection system), without using the sputtering or photolithography.

Then, as shown in FIG. 6(b), a transfer substrate 61 with a plurality of generating elements 53 formed thereon is aligned and disposed opposite the substrate 52.

The electrically conductive adhesive 56 is then cured under heating and pressure in the longitudinal direction, as shown in the figure. As a result, the generating elements 53 and wiring 55 (and substrate 52) are adhesively bonded via the electrically conductive adhesive 56. At the same time, the electrically conductive particles (not shown in the figure) that are present in the electrically conductive adhesive 56 are connected (brought into contact) in the longitudinal direction, as shown in the figure, and the generating elements 53 and wiring 55 are electrically connected via the conductive particles.

Then, the prescribed generating elements 53 among a plurality of the generating elements 53 are selectively (locally) illuminated with an illumination light L from the rear side (the side of the illumination light incidence surface 62a) of the transparent heat-resistant substrate 62 (see FIG. 6(b)). This illumination light L falls on the peeling layer 63 from the interface side after passing through the substrate 62.

Any radiation causing intralayer and/or interface peeling in the peeling layer 63 may be used as the illumination light L. Examples of suitable radiation include X rays, UV rays, visible light, IR radiation (heat rays), laser beam, milliwave radiation, microwave radiation, electron beam, and radioactive rays (alpha rays, beta rays, gamma rays). Among them, laser beam may be preferred from the standpoint of easiness of causing the peeling (ablation) of the peeling layer 63. Examples of lasers that can be used as the laser devices to generate such laser beam include a variety of gas lasers and solid lasers (semiconductor lasers). The preferred examples of suitable lasers include excimer lasers, Nd-YAG laser, Ar laser, CO₂ laser, CO laser, and He—Ne laser. Among them, excimer lasers are especially preferred. Because excimer lasers output high energy in a short wavelength range, they can cause ablation in the peeling layer 63 within a very short time. Therefore, the peeling layer 63 can be peeled without causing any temperature increase in the adjacent or closely located generating elements 53 and substrate 62 or the like, that is, without causing deterioration or damage.

As a result, intralayer peeling and/or interface peeling occurs in the peeling layer 63 and the bonding forces are reduced or eliminated. Therefore, if the substrate 62 and generating elements 53 are separated, as shown in FIG. 6(c), the generating elements 53 are separated from the substrate 62 and transferred onto the substrate 52.

Then, a lens forming material, such as a transparent resin, is coated on top (light incidence side of generating elements 53) of the generating elements 53 by using the aforementioned droplet ejection device IJ.

It is especially preferred that a material of a non-solvent system be used as the transparent resin. A transparent resin of a non-solvent system is obtained in liquid form, for example, by diluting the transparent resin with a monomer thereof, thereby enabling the ejection from the droplet ejection head 1, without producing a liquid body by dissolving the transparent resin in an organic solvent. Examples of suitable results include thermoplastic or thermosetting resins, such as acrylic resins, e.g., polymethyl methacrylate, polyhydroxyethyl methacrylate, and polycyclohexyl methacryalte, allyl resins, e.g., polydiethylene glycol bis-allyl carbonate and polycarbonates, methacrylic resins, polyurethane resins, polyester resins, polyvinyl chloride resins, polyvinyl acetate resins, cellulose resins, polyamide resins, fluorine-containing resins, polypropylene resins, and polystyrene resins. Those resins can be used individually or in mixtures of a plurality thereof.

In the present example, a radiation-curable resin is used as the transparent resin. In addition to radiation-curable resins, thermosetting resins or resins obtained by mixing a plurality of resins and conducting curing reaction can be also used. The radiation-curable resins are obtained by blending a photopolymerization initiator, such as a biimidazole compound with the aforementioned transparent resin. Blending with the photopolymerization initiator provides a resin with radiation curability. The radiation as referred to herein is a general term describing visual light, ultraviolet (UV) rays, IR rays, X rays, electron beam and the like. UV rays are generally used.

The surface tension of the transparent resin is preferably within a range of from 0.02 N/m to 0.05 N/m. If the surface tension is less than 0.02 N/m when droplets are ejected by a droplet ejection method, wettability of the nozzle surface with the droplets increases, easily bending a flying path. If the surface tension is above 0.05 N/m, the shape of the meniscus at the distal end of the nozzle is unstable. As a result, the ejection amount and ejection timing are difficult to control. In order to adjust the surface tension, an agent adjusting the surface tension, for example, of a fluorine, silicone, or nonionic system, may be added to the aforementioned dispersion in a very small amount within a range causing no significant decrease in contact angle with the substrate and producing no effect on optical properties such as refractive index. Nonionic agents adjusting the surface tension serve to increase the wettability of the substrate with the ink, enhance leveling properties of the film, and reduce or prevent the appearance of fine peaks and valleys on the film. If necessary, the agents to adjust the surface tension may contain organic compounds such as alcohols, ethers, esters, and ketones.

The viscosity of the transparent resin is preferably within a range of from 1 mPa.s to 200 mPa.s. If the viscosity is less than 1 mPa.s when the ink is ejected in the form of droplets by using a droplet ejection method, the peripheral portions of the nozzle are easily contaminated by the ink flowing out therefrom. Further, when the viscosity is above 50 mPa.s, the ejection can be conducted by providing an ink heating mechanism either on the head or on the droplet ejection device. However, the frequency of nozzle clogging at normal temperature increases and the droplets are difficult to eject smoothly. When the viscosity is above 200 mPa.s, the viscosity is difficult to decrease to a level enabling the ejection of droplets, even by heating.

One or a plurality of droplets of such radiation-curable transparent resin are ejected onto the substrate 52 (generating element 53) according to the size of the desired lens portion (microlens) 54. As a result, the transparent resin composed of the droplets assumes the convex shape (almost semispherical shape) shown in FIG. 2 due to surface tension thereof.

Once the transparent resin in the prescribed amount corresponding to a single microlens that has to be formed has been ejected and coated, and then this coating operation has been repeated to obtain the desired number of lens portions 54, the transparent resin is cured by irradiating with radiation, such as UV rays.

As a result, as shown in FIG. 2, when no lens portions 54 were formed, the light that did not fall on the generating elements 53 can be guided to the generating elements 53.

Further, when the focal positions of the lens portions 54 coincide with the light-receiving surface of the generating elements 53 or close thereto, the light-receiving surface area of the generating elements 53 decreases. Therefore, it may be preferred that the focal distance (size) of the lens portions 54 be set so that the entire light receiving surface of the generating elements 53 serves as a light-receiving surface area.

As described hereinabove, in the present exemplary embodiment, because lens portions 54 are formed on the light incidence side of generating elements 53, the aperture ratio can be increased. As a result, a large amount of light can be converged and guided to the generating elements 53 and the power generation efficiency can be greatly increased.

Further, in the present exemplary embodiment, the lens portions 54 are formed by a droplet ejection system. Therefore, a lens shape having a spherical surface (part thereof) can be easily formed by surface tension of the droplets. Moreover, because the alignment with the generating elements 53 is provided by self-arrangement of the droplets, it is not necessary to conduct a separate alignment of optical axes and a contribution can also be made to increase the productivity.

Further, in the present exemplary embodiment, the generating elements 53 and lens portions 54 are disposed on the substrate 52 in a zigzag formation. Therefore, a large number of generating elements 53 and lens portions 54 can be provided and the light falling on the solar cell device 51 can be received efficiently and employed for power generation.

Moreover, in the present exemplary embodiment, the generating elements 53 formed on the transfer substrate 61 are transferred onto the substrate 52. Therefore, a plurality of generating elements 53 can be integrally manufactured on the transfer substrate 61, the surface area efficiency in manufacturing the elements can be greatly increased by comparison with the case where the generating elements 53 are directly formed on the substrate 52, and a large substrate 52 with generating elements 53 disposed thereon in a dispersed fashion can be manufactured with good efficiency and at a low cost.

Further, in the present exemplary embodiment, some (part portions) of a plurality of generating elements 53 formed on the transfer substrate 61 are selected and transferred. Therefore, the generating elements 53 can be easily disposed in any number and in any position on the substrate 52, and a thinned-out disposition can be obtained according to circumstances. Further, the generating elements 53 manufactured on the transfer substrate 61 can be sorted and removed prior to the transfer and the production yield can be increased.

### Second Exemplary Embodiment

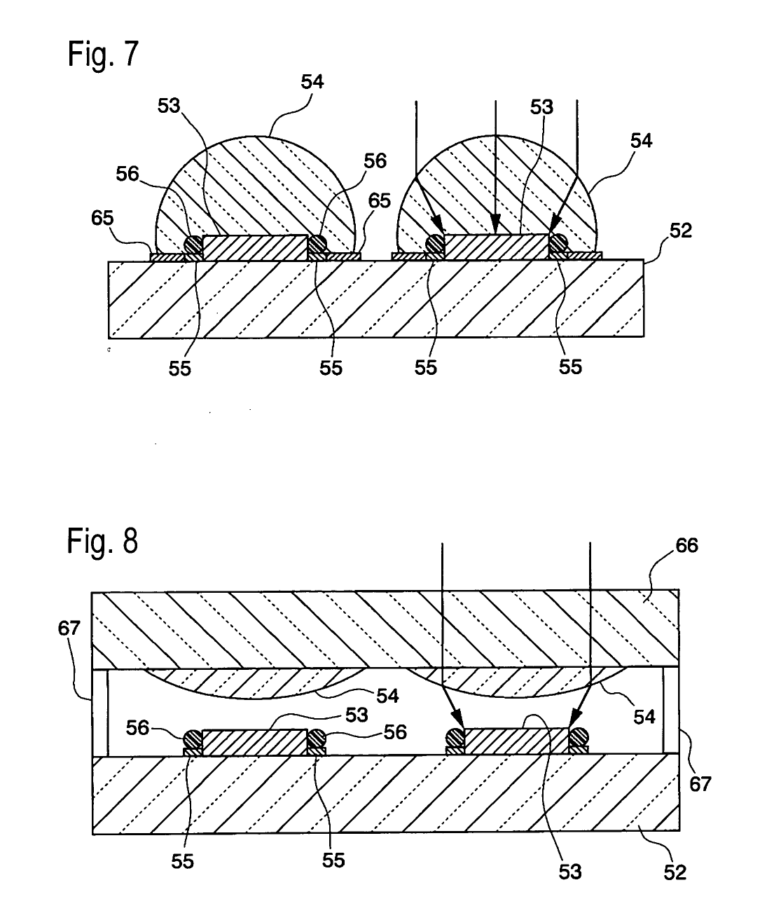

FIG. 7 illustrates the second exemplary embodiment of the solar cell device in accordance with the present invention.

In this figure, the elements identical to the structural elements of the first exemplary embodiment shown in FIG. 2 are assigned with the same reference numerals and explanation thereof is omitted

In the second exemplary embodiment, a bank (protrusion) 65 having lyophilic property is provided, with a difference in level with the substrate 52, around the generating elements 53 located on the substrate 52.

The bank 65 can be formed by any method, such as a lithography method or printing methods. For example, when a lithography method is used, an organic photosensitive material is coated to match the height of the bank on the substrate 52 by the prescribed method, such as spin coating, spray coating, roll coating, die coating, or dip coating, and a resist layer is coated thereon. Then, a mask is produced according to the bank shape (wiring pattern) and the resist is exposed and developed to leave the resist matching the bank shape. Finally, etching is conducted to remove the bank material in the portion outside the mask. Furthermore, the bank (convex portion) may be also formed in two or more layers wherein the lower layer is composed on an inorganic substance and the upper layer is composed of an organic substance.

For example, polymer materials, such as acrylic resins, polyimide resins, olefin reins, and melamine resins can be used as the organic materials to form the bank 65. The bank 65 patterned to the prescribed shape is lyophilized (for example, to a contact angle of 10° of less) by ultraviolet (UV) irradiation treatment comprising irradiating with UV rays or by O₂ plasma treatment using oxygen as a treatment gas in the air atmosphere.

For example, the O₂ plasma treatment is conducted by treating the substrate 52 with oxygen in a plasma state from a plasma discharge electrodes. The treatment conditions can be as follows: plasma power 50-1000 W, oxygen gas flow rate 50-100 mL/min, transportation rate of the substrate 52 with respect to the plasma electrode 0.5-10 mm/sec, and substrate temperature 70-90° C.

In other aspects, the present exemplary embodiment is identical to the first exemplary embodiment.

In the present exemplary embodiment, the droplets that were ejected on the generating elements 53 and placed on the bank 65 were not repelled. Therefore, they are held on the bank 65, without flowing down from the bank 65. As a result, a large number of droplets can be coated, lens portions 54 with a shape closer to the spherical shape can be formed, and the focal distance (focal position) of the lens portions 54 can be finely adjusted by adjusting the amount of the formed and falling droplets.

### Third Exemplary Embodiment

The third exemplary embodiment of the solar cell device in accordance with the present invention is described below with reference to FIG. 8.

In the first and second exemplary embodiments, the lens portions were formed on the generating elements 53. However, in the present exemplary embodiment, the lens portions 54 are provided separately from the generating elements 53.

Thus, in the present exemplary embodiment, as shown in FIG. 8, a substrate 52 provided with generating elements 53 and an auxiliary substrate (third substrate) 66 formed from glass or the like and provided with lens portions 54 are disposed so as to face each other.

The auxiliary substrate 66 is supported via a spacer 67 with respect to the substrate 52 and the distance thereof from the substrate 52 can be adjusted by adjusting the height of the spacer 67.

Therefore, in the present exemplary embodiment, the adjustment of the focal position of the lens portions 54 is facilitated and the light illumination range of the generating elements 53 can be changed in a simple manner. As a result, it is possible to deal easily even with changes in the light-receiving surface area of the generating elements 53.

### Fourth Exemplary Embodiment

An electronic device equipped with the above-described solar cell device 1 is described below.

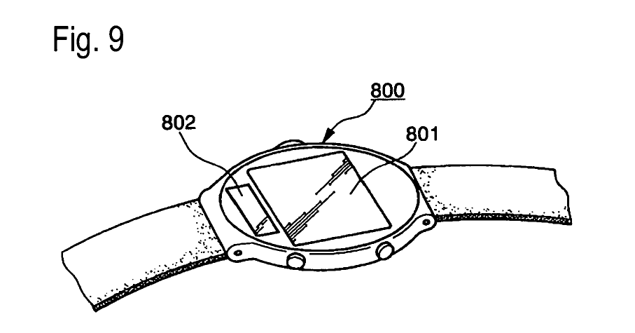

FIG. 9 is a perspective view showing an example of a watch-type electronic device.

Referring to FIG. 9, reference numeral 800 indicates a watch body, 801—a display portion equipped with an organic EL display body or liquid-crystal display body, and 802—a power source unit equipped with the solar cell device 51 of the above-described exemplary embodiments.

Because this watch-type electronic device is equipped with the above-described solar cell device 51, it has an inexpensive power source with a high power generation efficiency, and a low-cost electronic device with excellent power generation efficiency can be obtained.

Exemplary embodiments of the present invention are described above with reference to the appended drawings. However, the present invention is not limited to those examples. The shape and combinations of constituent components shown in the above-described exemplary embodiments are merely illustrative and various changes based on the design requirements can be made without departing from the spirit of the invention.

For example, in the above-described exemplary embodiments, the generating elements 53 were provided on the substrate 52 by transfer, but this feature is not limiting and the lens portions 54 may be directly provided on the substrate where the generating elements 53 were formed. Furthermore, in the above-described exemplary embodiments, a zigzag disposition of the generating elements 53 and lens portions 54 is preferred, but such a disposition is not limiting and they may be disposed, for example, as a grid.

Furthermore, the electronic device is not limited to a watch, and the present invention can be also applied to wall clocks, table clocks, portable information terminals and the like, for example.

What is claimed is:

1. A solar cell device, comprising:
a substrate;
a plurality of generating elements, that generate electricity under an effect of incident light, formed on the substrate; and
lens portions provided on an incidence side of the light for each of the generating elements, converging the light and guiding the light to the generating elements.

2. The solar cell device according to claim 1, further including a second substrate that is different from the substrate, the generating elements being formed on the second substrate and being peeled off from the second substrate and transferred onto the substrate.

3. The solar cell device according to claim 2, a plurality of the generating elements being formed on the second substrate, and
some generating elements of the plurality of generating elements on the second substrate being selectively transferred onto the substrate.

4. The solar cell device according to claim 1, the lens portions being formed by a liquid drop ejection system.

5. The solar cell device according to claim 4, further including a third substrate, the lens portions being provided on the third substrate so supported that a distance therefrom to the substrate can be adjusted.

6. The solar cell device according to claim 4, the lens portions being provided so as to cover the generating elements.

7. The solar cell device according to claim 5, further including a protrusion having a lyophilic property, with a difference in level with the substrate, around the generating elements.

8. The solar cell device according to claim 1, the generating elements being disposed in a zigzag formation on the substrate.

9. An electronic device, comprising:
the solar cell device according to claim 1 usable as a power source unit.

10. A method of manufacturing a solar cell device that includes a plurality of generating elements, that generate electricity under an effect of incident light, and that are formed on a substrate, comprising:
providing lens portions converging the light and guiding the light to the generating elements on an incidence side of the light for each of the generating elements.
